(19) United States
(12) Patent Application Publication
(10) Pub. No.: US 2025/0079072 A1
(43) Pub. Date: Mar. 6, 2025

(54) Inductor and Manufacturing Method Therefor, Filter, and Electronic Device

(71) Applicants: BOE Technology Group Co., Ltd., Beijing (CN); Beijing BOE Optoelectronics Technology Co., Ltd., Beijing (CN)

(72) Inventors: Yulin FENG, Beijing (CN); Yue LI, Beijing (CN); Yuelei XIAO, Beijing (CN); Xue CAO, Beijing (CN); Huiying LI, Beijing (CN); Kidong HAN, Beijing (CN); Yifan WU, Beijing (CN); Wenbo CHANG, Beijing (CN); Qichang AN, Beijing (CN); Qiuxu WEI, Beijing (CN); Lihui WANG, Beijing (CN); Biqi LI, Beijing (CN)

(21) Appl. No.: 18/279,055

(22) PCT Filed: Oct. 20, 2022
(86) PCT No.: PCT/CN2022/126395

§ 371 Date: Aug. 26, 2023

(51) Int. Cl. H01F 27/29; H01F 27/32; H01F 41/06; H03H 7/01

(52) U.S. Cl. CPC H01F 27/29; H01F 27/323; H01F 41/06; H03H 7/0115

(57) ABSTRACT

The present disclosure provides an inductor, a manufacturing method therefor, a filter and an electronic device, belongs to the technical field of passive devices. The inductor according to the present disclosure includes a dielectric substrate and N coil structures disposed on the dielectric substrate; the N coil structures are nested and electrically connected in sequence, wherein N is an integer greater than or equal to 2. Any one of the coil structures includes a plurality of layers of sub-coils disposed on the dielectric substrate in sequence, and at least one interlayer insulating layer is disposed between sub-coils disposed adjacently, and adjacent layers of sub-coils are electrically connected through a first connection via penetrating the interlayer insulating layer between the adjacent layers of sub-coils.

### CROSS-REFERENCE TO RELATED APPLICATION

The present application is a U.S. National Phase Entry of International Application No. PCT/CN2022/126395 having an international filing date of Oct. 20, 2022, the entire content of which is hereby incorporated by reference.

### TECHNICAL FIELD

The present disclosure belongs to the technical field of passive devices, in particular to an inductor, a manufacturing method therefor, a filter and an electronic device.

### BACKGROUND

With rapid development of mobile communication technologies, a speed of signal transmission has increased rapidly. From a 2G era to a 5G era, a speed of signal transmission in an order of KB/s has been increased to a speed of signal transmission in an order of GB/s. The increase in speed has accelerated development of electronic devices and a progress in the electronic age. A frequency band of signal transmission has also been developed from the initial 100 MHz to the RF GHz, and evolves from centimeter waves to millimeter waves. Therefore, high speed, low delay and large connectivity etc. have become main characteristics of an RF field.

With the development of communication technologies, higher requirements are put forward for performances and dimensions of electronic elements. With a decrease of the dimensions of the electronic elements, the Integrated Product Development (IPD for short) technology, the Micro Electro Mechanical Systems (MEMS for short) technology, the nanotechnology and other new technologies emerge constantly. At present, the dimensions of the electronic elements have developed rapidly, and the dimensions of the electronic elements have been developed from the order of centimeters to the order of millimeters, micrometers, even nanometers. Passive devices in the electronic elements are essential basic elements in all kinds of equipment, including resistors, capacitors and inductors. The Integrated Product Development (IPD for short) technology can effectively reduce dimensions of discrete elements and component combination routing by integrating most widespread passive devices in the electronic elements.

Inductors are crucial components of the electronic elements. The inductors can be used as discrete devices or operate as a part of circuit components, such as connecting traces in common LC filters or package carrier boards. Due to a spiral structure of traditional inductors, inductors accounts for a large proportion of area in passive devices, so the miniaturization and performance optimization of the inductors are a crucial part of inductor development.

### SUMMARY

The invention aims at solving at least one of the technical problems existing in the prior art, and providing an inductor and a manufacturing method therefor, a filter, and an electronic device.

In a first aspect, an inductor is provided in an embodiment of the present disclosure. The inductor includes a dielectric substrate and N coil structures disposed on the dielectric substrate, the N coil structures are nested and electrically connected in sequence, wherein N is an integer greater than or equal to 2; wherein, any one of the coil structures includes a plurality of layers of sub-coils disposed on the dielectric substrate in sequence, and at least one interlayer insulating layer is disposed between sub-coils disposed adjacently, and adjacent layers of sub-coils are electrically connected through a first connection via penetrating the interlayer insulating layer between the adjacent layers of sub-coils.

The inductor further includes a first lead terminal and a second lead terminal, wherein the first lead terminal is electrically connected to a head end of a first coil structure, and the second lead terminal is electrically connected to a tail end of an N-th coil structure.

The first lead terminal and the second lead terminal are disposed in a same layer and of a same material.

The first lead terminal is electrically connected to a first layer of sub-coil of the first coil structure in a direction away from the dielectric substrate, and the second lead terminal is electrically connected to a first layer of sub-coil of the N-th coil structure in the direction away from the dielectric substrate.

The second lead terminal is disposed in a same layer as a first layer of sub-coil of the first coil structure in the direction away from the dielectric substrate, and the second lead terminal and the first layer of sub-coil of the N-th coil structure are integrally formed; and/or
the second lead terminal is disposed in a same layer as the first layer of sub-coil of the N-th coil structure in the direction away from the dielectric substrate, and the second lead terminal and the first layer of sub-coil of the N-th coil structure are integrally formed.

The first lead terminal is electrically connected to a last layer of sub-coil of the first coil structure in a direction away from the dielectric substrate, and the second lead terminal is electrically connected to a last layer of sub-coil of the N-th coil structure in the direction away from the dielectric substrate.

The first lead terminal is disposed in a same layer as the last layer of sub-coil of the first coil structure in the direction away from the dielectric substrate, and the first lead terminal and the last layer of sub-coil of the first coil structure are integrally formed; and/or,
the second lead terminal is disposed in a same layer as the last layer of sub-coil of the N-th coil structure in the direction away from the dielectric substrate, and the second lead terminal and the last layer of sub-coil of the N-th coil structure are integrally formed.

Each of the N coil structures includes M layers of sub-coils, wherein M is an integer greater than or equal to 2; sub-coils of k-th layers in all coil structures are disposed in a same layer, wherein k is an integer greater than or equal to 1 and less than or equal to N.

Quantities of layers in at least two coil structures in the N coil structures are not equal;
for any two of the coil structures with unequal quantities of layers of sub-coils, one of the any two coil structures includes P layers of sub-coils, and the other one of the any two coil structures includes Q layers of sub-coils; a coil structure including the P layers of sub-coils is referred to as a first coil structure, and a coil structure including the Q layers of sub-coils is referred to as a second coil structure, wherein P is an integer greater than or equal to 2, Q is an integer greater than or equal to 2, and P is greater than Q;
an i-th layer of sub-coil in the first coil structure and the i-th layer of sub-coil in the second coil structure are disposed in a same layer, and an (i+k)-th layer of sub-coil in the first coil structure and an (i+1)-th layer of sub-coil in the second coil structure are disposed in a same layer, wherein i is an integer greater than or equal to 1 and less than or equal to N, and k is an integer greater than or equal to 2 and less than or equal to N−i;
an i-th layer of sub-coil and an (i+1)-th layer of sub-coil of the second coil structure are electrically connected through a transfer electrode that is composed of at least one layer of sub-coil in (i+2)-th to (i+k−1)-th layers of sub-coils in the first coil structure.

In a second aspect, a method for manufacturing an inductor is provided in an embodiment of the present disclosure. The method includes: providing a dielectric substrate, forming N coil structures on the dielectric substrate, the N coil structures are nested and electrically connected in sequence; wherein N is an integer greater than or equal to 2; wherein the act of forming any coil structure includes:
forming, in sequence, a plurality of layers of sub-coils and at least one interlayer insulating layer between adjacent layers of sub-coils on the dielectric substrate; wherein adjacent layers of sub-coils are electrically connected through a first connection via penetrating the interlayer insulating layer between the adjacent layers of sub-coils.

The method for manufacturing an inductor further includes forming a first lead terminal and a second lead terminal on the dielectric substrate, wherein the first lead terminal is electrically connected to a head end of a first coil structure, and the second lead terminal is electrically connected to a tail end of an N-th coil structure.

The first lead terminal and a first layer of sub-coil of the first coil structure in the direction away from the dielectric substrate are formed by a single patterning process; and/or
the second lead terminal and a first layer of sub-coil of the N-th coil structure in the direction away from the dielectric substrate are formed by a single patterning process.

According to the method for manufacturing an inductor, the first lead terminal and a last layer of sub-coil of the first coil structure in the direction away from the dielectric substrate are formed by a single patterning process; and/or,
the second lead terminal and a last layer of sub-coil of the N-th coil structure in the direction away from the dielectric substrate are formed by a single patterning process.

Each of the N coil structures includes M layers of sub-coils, wherein M is an integer greater than or equal to 2; sub-coils of k-th layers in all coil structures are formed by a single patterning process, wherein k is an integer greater than or equal to 1 and less than or equal to N.

Quantities of layers in at least two coil structures in the N coil structures are not equal;
for any two of the coil structures with unequal quantities of layers of sub-coils, one of the any two coil structures includes P layers of sub-coils, and the other one of the any two coil structures includes Q layers of sub-coils; a coil structure including the P layers of sub-coils is referred to as a first coil structure, and a coil structure including the Q layers of sub-coils is referred to as a second coil structure, wherein P is an integer greater than or equal to 2, Q is an integer greater than or equal to 2, and P is greater than Q;
an i-th layer of sub-coil in the first coil structure and the i-th layer of sub-coil in the second coil structure are formed by a single patterning process, and an (i+k)-th layer of sub-coil in the first coil structure and an (i+1)-th layer of sub-coil in the second coil structure are formed by a single patterning process, wherein i is an integer greater than or equal to 1 and less than or equal to N, and k is an integer greater than or equal to 2 and less than or equal to N−i;
an i-th layer of sub-coil and an (i+1)-th layer of sub-coil of the second coil structure are electrically connected through a transfer electrode that is composed of at least one layer of sub-coil in (i+2)-th to (i+k−1)-th layers of sub-coils in the first coil structure.

In a third aspect, a filter that includes any of the inductors described above is provided in an embodiment of the present disclosure.

In a fourth aspect, an electronic device that includes the filter described above is provided in an embodiment of the present disclosure.

### BRIEF DESCRIPTION OF DRAWINGS

FIG. 1 is a front view of an inductor (a first example) according to an embodiment of the present disclosure.

FIG. 2 is a top view of the inductor shown in FIG. 1.

FIG. 3 is a side view of the inductor shown in FIG. 1.

FIG. 4 is a front view of an inductor in a second example according to an embodiment of the present disclosure.

FIG. 5 is a top view of the inductor in the second example according to an embodiment of the present disclosure.

FIG. 6 is a side view of the inductor in the second example according to an embodiment of the present disclosure.

FIG. 7 is a front view of an inductor in a third example according to an embodiment of the present disclosure.

FIG. 8 is a top view of the inductor in the third example according to an embodiment of the present disclosure.

FIG. 9 is a side view of the inductor in the third example according to an embodiment of the present disclosure.

FIG. 10 is a front view of an inductor in a fourth example according to an embodiment of the present disclosure.

FIG. 11 is a top view of the inductor in the fourth example according to an embodiment of the present disclosure.

FIG. 12 is a side view of the inductor in the fourth example according to an embodiment of the present disclosure.

FIG. 13 is a front view of an inductor in a fifth example according to an embodiment of the present disclosure.

FIG. 14 is a top view of the inductor in the fifth example according to an embodiment of the present disclosure.

FIG. 15 is a side view of the inductor in the fifth example according to an embodiment of the present disclosure.

FIG. 16 is a schematic diagram of an intermediate product formed in act S11 of a method for manufacturing an inductor according to an embodiment of the present disclosure.

FIG. 17 is a schematic diagram of an intermediate product formed in act S12 of the method for manufacturing an inductor according to an embodiment of the present disclosure.

FIG. 18 is a schematic diagram of an intermediate product formed in act S13 of the method for manufacturing an inductor according to an embodiment of the present disclosure.

FIG. 19 is a schematic diagram of an intermediate product formed in act S14 of the method for manufacturing an inductor according to an embodiment of the present disclosure.

FIG. 20 is a schematic diagram of an intermediate product formed in act S15 of the method for manufacturing an inductor according to an embodiment of the present disclosure.

FIG. 21 is a schematic diagram of an intermediate product formed in act S16 of the method for manufacturing an inductor according to an embodiment of the present disclosure.

FIG. 22 is a schematic diagram of an intermediate product formed in act S17 of the method for manufacturing an inductor according to an embodiment of the present disclosure.

FIG. 23 is a schematic diagram of an intermediate product formed in act S18 of the method for manufacturing an inductor according to an embodiment of the present disclosure.

FIG. 24 is a schematic diagram of an intermediate product formed in act S19 of the method for manufacturing an inductor according to an embodiment of the present disclosure.

### DETAILED DESCRIPTION

To enable those skilled in the art to better understand the technical solutions of the present invention, a further detailed description of the present invention is given below in conjunction with the accompanying drawings and detailed description.

Unless otherwise defined, technical terms or scientific terms used in the present disclosure should have the meanings as commonly understood by those of ordinary skill in the art that the present disclosure belongs to. The “first”, “second” and similar terms used in the present disclosure do not indicate any order, quantity, or importance, but are used only for distinguishing different components. Similarly, similar words such as “a”, “an” or “the” do not denote a limitation on quantity, but rather denote the presence of at least one. “Include”, “contain”, or similar words mean that elements or objects appearing before the words cover elements or objects listed after the words and their equivalents, but do not exclude other elements or objects. “Connect”, “join”, or a similar term is not limited to a physical or mechanical connection, but may include an electrical connection, whether direct or indirect. “Upper”, “lower”, “left”, “right”, etc., are used to represent relative position relations, and when an absolute position of a described object is changed, the relative position relation may also be correspondingly changed.

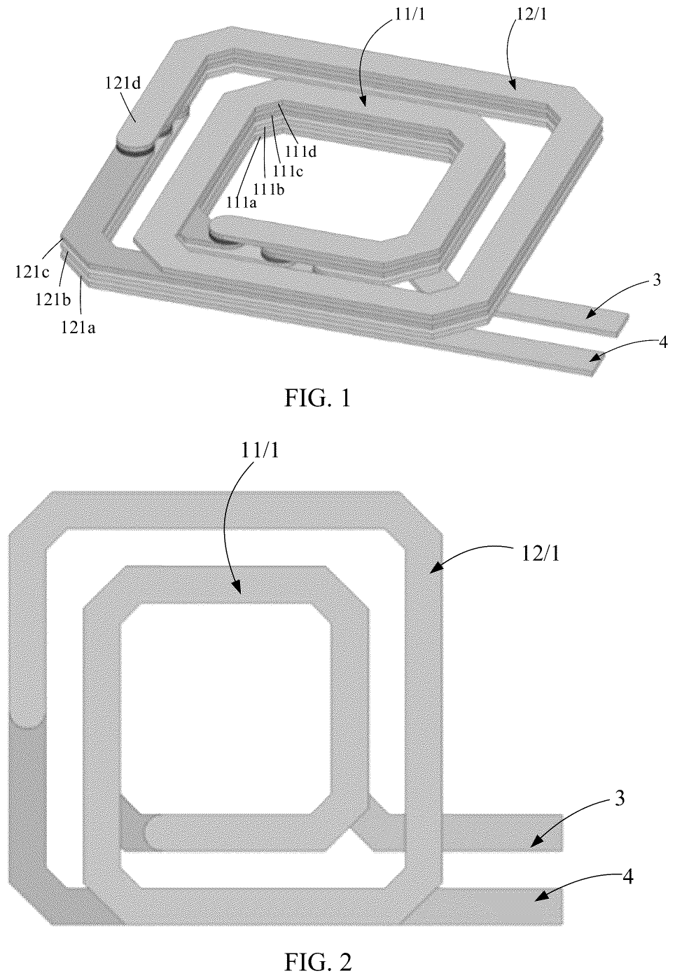

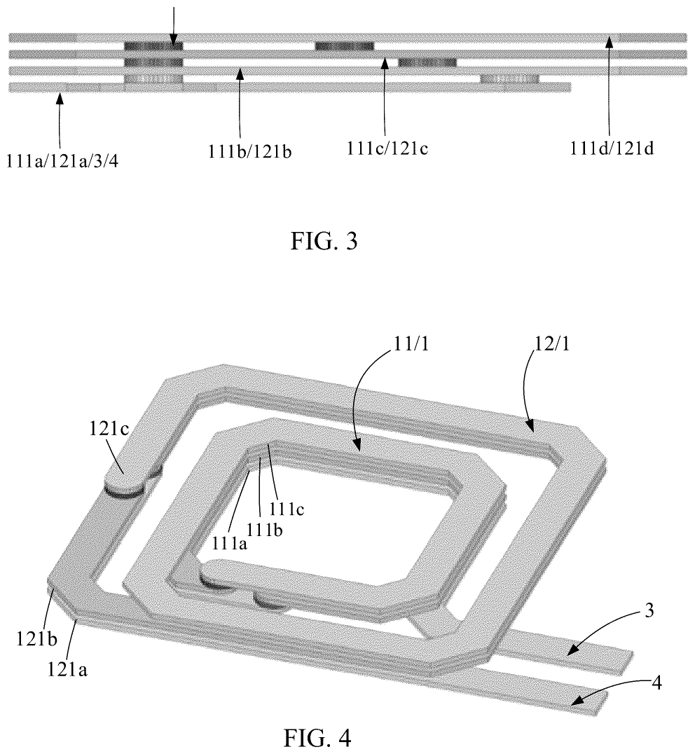

In a first aspect, FIG. 1 is a front view of an inductor (a first example) according to an embodiment of the present disclosure, FIG. 2 is a top view of the inductor shown in FIG. 1, and FIG. 3 is a side view of the inductor shown in FIG. 1. As shown in FIGS. 1-3, an inductor is provided in an embodiment of the present disclosure. The inductor includes a dielectric substrate and N coil structures disposed on the dielectric substrate, and the N coil structures 1 are nested and electrically connected in sequence, wherein N is an integer greater than or equal to 2. Each coil structure 1 includes a plurality of layers of sub-coils disposed on a dielectric substrate in sequence, and at least one interlayer insulating layer is disposed between sub-coils disposed adjacently, and adjacent layers of sub-coils are electrically connected through a first connection via 131 penetrating the interlayer insulating layer between the adjacent layers of sub-coils.

It should be noted that in an embodiment of the present disclosure, an innermost coil is considered as a first coil structure, an outermost coil is considered as an N-th coil structure, and N coil structures are arranged in sequence from inside to outside. An end of an h-th coil structure is electrically connected with an end of an (h+1)-th coil structure, wherein h is an integer greater than or equal to 1, and less than N. In FIGS. 1-3, the inductor includes only two coil structures, i.e., a first coil structure 11 and a second coil structure 12. The first coil structure 11 and the second coil structure 12 both include four layers of sub-coils. The four layers of sub-coils of the first coil structure 11 are indicated by 111a, 111b, 111c, 111d, sequentially, in a direction away from the dielectric substrate, and the four layers of sub-coils of the second coil structure 12 are indicated by 121a, 121b, 121c and 121d, sequentially, in a direction away from the dielectric substrate.

Each coil structure 1 of the inductor provided in an embodiment of the present disclosure is formed by electrically connecting a plurality of layers of sub-coils, which can effectively increase a wiring length of the inductor, and with an increase of the wiring length of the inductor per unit area, an inductance density can be improved. Meanwhile, since the inductor is composed of a plurality of nested coil structures 1, an effective mutual inductance can be formed between an inner coil structure 1 and an outer coil structure 1 by controlling current flow directions of the coil structures 1, and the inductance density can be further improved.

Specifically, a formula for inductance is as follows:

$${L}_{IPD} = \frac{μL}{2 π} [ ln \frac{2 L}{W + t} + \frac{1}{2} ]$$

L is a total length of the sub-coils, y is a permeability of a material of the sub-coils, wherein W and t are a width and a thickness of the sub-coil, respectively. According to the formula, an increase of the total length of the sub-coils linearly increases an inductance value. The plurality of coil structures may not increase an excessive element area, but can multiply the inductance value.

Meanwhile, according to the above-mentioned design, a current direction of an outer wiring being consistent with a current direction of an inner wiring can be ensured, and mutual inductance can be generated between coil structures in a same direction to further increase the inductance value. A formula for the mutual inductance is as follows,

$${M}_{RDL} = \frac{μ Lo}{2 π} \{ ln [ \frac{{L}_{O}}{d} + \sqrt{1 + {( \frac{{L}_{O}}{d} )}^{2}} ] - \sqrt{1 + {( \frac{d}{{L}_{O}} )}^{2}} + \frac{d}{{L}_{O}} \}$$

where d is a distance between centers of two coil structures, and needs to be calculated for different conductive layers. Lo is an opposite length of two coil structures, and is a permeability of a material of the coil structures. Since the mutual inductance does not exist in a part of the inductor where there is no outer coil structure, the increased mutual inductance is effective inductance, which further increases the inductance value.

In some examples, the inductor includes not only the above-mentioned structure, but also a first lead terminal 3 and a second lead terminal 4. For the N coil structures 1, a head end of a first coil structure is connected to the first lead terminal 3, and a tail end of an N-th coil structure 1 is connected to the second lead terminal 4, so as to be electrically connected to other elements of a circuit through the first lead terminal 3 and the second lead terminal 4.

Furthermore, since the N coil structures 1 are nested, the first lead terminal 3 and the second lead terminal 4 can be disposed in a same layer in an embodiment of the present disclosure, thereby the head end of the first coil structure is connected to the first lead terminal 3, and the tail end of the N-th coil structure is connected to the second lead terminal 4. In this case, the first lead terminal 3 and the second lead terminal 4 are disposed in the same layer, which is beneficial to the electrical connection between the inductor and other elements in the circuit, and can shorten an interconnected wiring in circuit connecting, avoids an interference by the connection through the via when the first lead terminal 3 and the second lead terminal 4 are located in different layers in a traditional inductor structure, and improves accuracy of an inductor design.

In an example, when a head end of a layer of sub-coil, which is closest to the dielectric substrate, in the first coil structure serves as the head end of the first coil structure, the first lead terminal 3 may be disposed in a same layer as the layer of sub-coil, which is closest to the dielectric substrate, in the first coil structure, and the first lead terminal 3 and the layer of sub-coil, which is closest to the dielectric substrate, in the first coil structure are integrally formed. That is, the first lead terminal 3 may be formed while a first layer of sub-coil of the first coil structure is being formed on the dielectric substrate, in this case, process steps and production costs are not increased. Similarly, when a tail end of a layer of sub-coil, which is closest to the dielectric substrate, in the N-th coil structure serves as the tail end of the N-th coil structure, the second lead terminal 4 may be disposed in a same layer as the layer of sub-coil, which is closest to the dielectric substrate, in the N-th coil structure, and the second lead terminal 4 and the layer of sub-coil, which is closest to the dielectric substrate, in the N-th coil structure are integrally formed. That is, the second lead terminal 4 may be formed while a first layer of sub-coil of the N-th coil structure is being formed on the dielectric substrate, in this case process steps and production costs are not increased.

Certainly, the first lead terminal 3 may also be disposed on a side of the first coil structure close to the dielectric substrate, and the first lead terminal 3 is electrically connected to a head end of a layer of sub-structure, which is closest to the dielectric substrate, in the first coil structure through a second connection via. The second connection via penetrates an insulating layer between the first coil structure and the layer where the first lead terminal 3 is located. The second lead terminal 4 may also be disposed on a side of the N-th coil structure close to the dielectric substrate, and the second lead terminal 4 is electrically connected to a tail end of a layer of sub-structure, which is closest to the dielectric substrate, in the N-th coil structure through a third connection via. The third connection via penetrates an insulating layer between the N-th coil structure and the layer where the second lead terminal 4 is located.

In another example, when a head end of a layer of sub-coil, which is furthest from the dielectric substrate, in the first coil structure serves as the head end of the first coil structure, the first lead terminal 3 may be disposed in a same layer as the layer of sub-coil, which is furthest from the dielectric substrate, in the first coil structure, and the first lead terminal 3 and the layer of sub-coil, which is furthest from the dielectric substrate, in the first coil structure are integrally formed. That is, the first lead terminal 3 may be formed while a last layer of sub-coil of the first coil structure is being formed on the dielectric substrate, in this case, process steps and production costs are not increased. Similarly, when a tail end of a layer of sub-coil, which is furthest from the dielectric substrate, in the N-th coil structure serves as the tail end of the N-th coil structure, the second lead terminal 4 may be disposed in a same layer as the layer of sub-coil, which is furthest from the dielectric substrate, in the N-th coil structure, and the second lead terminal 4 and the layer of sub-coil, which is furthest from the dielectric substrate, in the N-th coil structure are integrally formed. That is, the second lead terminal 4 may be formed while a last layer of sub-coil of the N-th coil structure is being formed on the dielectric substrate, in this case, process steps and production costs are not increased.

Certainly, the first lead terminal 3 may also be disposed on a side of the first coil structure away from the dielectric substrate, and the first lead terminal 3 is electrically connected to a head end of a layer of sub-structure, which is furthest from the dielectric substrate, in the first coil structure through a second connection via. The second connection via penetrates an insulating layer between the first coil structure and the layer where the first lead terminal 3 is located. The second lead terminal 4 may also be disposed on a side of the N-th coil structure away from the dielectric substrate, and the second lead terminal 4 is electrically connected to a tail end of a layer of sub-structure, which is furthest from the dielectric substrate, in the N-th coil structure through a third connection via. The third connection via penetrates an insulating layer between the N-th coil structure and the layer where the second lead terminal 4 is located.

In some examples, each of the N coil structures 1 includes M layers of sub-coils, wherein M is an integer greater than or equal to 2. That is, quantities of layers of the sub-coils in all coil structures 1 are the same. Meanwhile, sub-coils of k-th layers in all coil structures 1 are disposed in a same layer, wherein k is an integer greater than or equal to 1 and less than or equal to N. For example, the sub-coils of all coil structures 1 are disposed in one-to-one correspondence, and corresponding sub-coils are disposed in a same layer. In this case, sub-coils, which are located in a same layer, of all coil structures 1 can be formed in a single composition process, which can effectively reduce an overall thickness of the inductor structure and achieve thinness and lightness of elements.

In some examples, the quantities of layers in at least two coil structures in the N coil structures 1 are not equal. For example, the quantities of layers of the sub-coils in all the N coil structures 1 are different. For another example, quantities of layers of sub-coils in a part of the N coil structures 1 are the same, quantities of layers of sub-coils in another part of the N coil structures 1 are the same, and the quantity of layers of sub-coils in the part of the N coil structures 1 is different from the quantity of layers of sub-coils in the another part of the N coil structures 1.

Further, for example, the quantities of layers of the sub-coils of any two coil structures 1 in the N coil structures 1 are different, one of the two is referred to as a first coil structure 11 and another one of the two is referred to as a second coil structure 12. The quantity of layers of sub-coils of the first coil structure 11 is P, and the quantity of layers of sub-coils of the second coil structure 12 is Q, wherein P is an integer greater than or equal to 2, Q is an integer greater than or equal to 2, and P is greater than Q. An i-th layer of sub-coil in the first coil structure 11 and the i-th layer of sub-coil in the second coil structure 12 are disposed in a same layer, and an (i+k)-th layer of sub-coil in the first coil structure 11 and an (i+1)-th layer of sub-coil in the second coil structure 12 are disposed in a same layer, wherein i is an integer greater than or equal to 1 and less than or equal to N, and k is an integer greater than or equal to 2 and less than or equal to N−i. An i-th layer of sub-coil and an (i+1)-th layer of sub-coil of the second coil structure 12 are electrically connected through a transfer electrode that is composed of at least one layer of sub-coil in (i+2)-th to (i+k−1)-th layers of sub-coils in the first coil structure 11.

In some examples, a material of the dielectric substrate may be a high insulation, low dielectric loss material such as glass, high resistance silicon, ceramics, etc. Preferably, glass is selected as the dielectric substrate, which has high dielectric constant and lower dielectric loss.

In order to more clearly explain a structure of an inductor according to an embodiment of the present disclosure, the inductor according to an embodiment of the present disclosure will be described below in connection with specific examples. In the following examples, the inductor includes two coil structure 1, that is, N=2. An inner coil structure 1 is referred to as a first coil structure 11 and an outer coil structure 1 is referred to as a second coil structure 12. However, it should be understood that the quantity of the coil structures 1 of the inductor is not limited to 2, and the quantity of the coil structures 1 of the inductor can be specifically designed according to an inductance value requirement on the inductor in an actual product. Meanwhile, in the following examples, for instance, the first lead terminal 3 and the second lead terminal 4 are disposed directly on the dielectric substrate.

In a first example, as shown in FIGS. 1-3, both the first coil structure 11 and the second coil structure 12 of the inductor include four layers of sub-coils disposed in sequence away from the dielectric substrate. The four layers of sub-coils of the first coil structure 11 are indicated by 111a, 111b, 111c and 111d, respectively. The four layers of sub-coils of the second coil structure 12 are indicated by 121a, 121b, 121c, and 121d, respectively. The first lead terminal 3 and the head end of the first layer of sub-coil 111a of the first coil structure 11 are electrically connected, disposed in a same layer and connected into an integrally-formed structure. The second lead terminal 4 and the head end of the first layer of sub-coil 121a of the second coil structure 12 are electrically connected, disposed in a same layer and connected into an integrally-formed structure. The four layers of sub-coils 111a, 111b, 111c, and 111d of the first coil structure 11 are arranged, respectively, in one-to-one correspondence with the four layers of sub-coils 121a, 121b, 121c, and 121d of the second coil structure 12, and the corresponding sub-coils are disposed in a same layer. An interlayer insulating layer is provided between adjacent layers of sub-coils, and adjacent sub-coils of the first coil structure 11 are electrically connected through a first connection via 131 penetrating the interlayer insulating layer between the sub-coils disposed adjacently. For example, a tail end of a first layer of sub-coil of the first coil structure 11 is electrically connected with a head end of the second layer of sub-coil through the first connection via 131. Similarly, adjacent sub-coils of the first coil structure 12 are electrically connected through a first connection via 131 penetrating the interlayer insulating layer between the sub-coils disposed adjacently. For example, a tail end of a first layer of sub-coil of the second coil structure 12 is electrically connected with a head end of the second layer of sub-coil through the first connection via 131.

In some examples, orthographic projections of various first connection vias 131 in the inductor are not overlapped on the dielectric substrate, effectively preventing the various first connection vias 131 from being centrally disposed to affect the yield of the inductor.

In some examples, line widths of each sub-coil, the first lead terminal 3, and the second lead terminal 4 may be set in a range of about 15-50 m, and the thickness of each sub-coil, the first lead terminal 3, and the second lead terminal 4 may be set in a range of about 0.1-10 m.

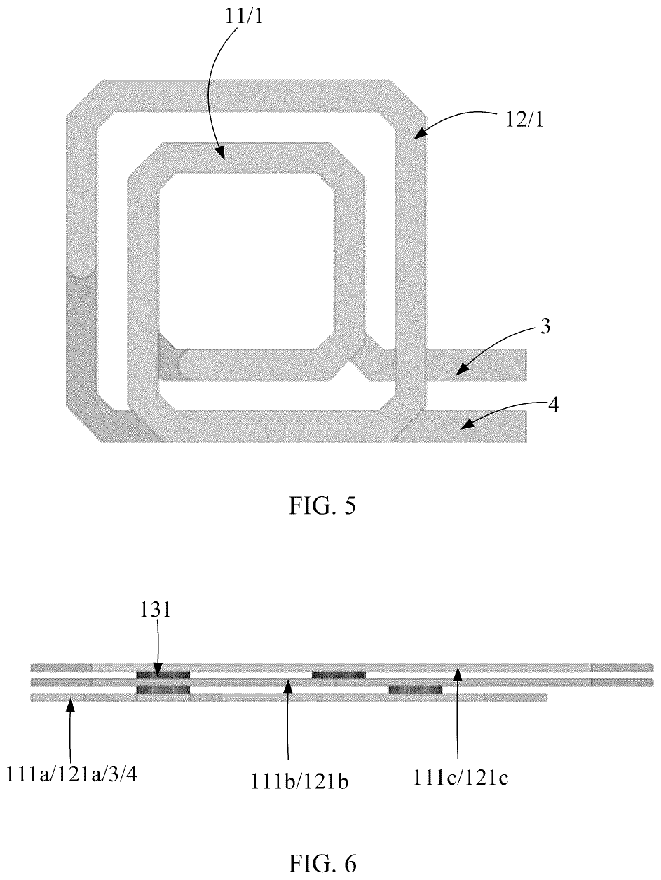

In a second example, FIG. 4 is a front view of an inductor in a second example according to an embodiment of the present disclosure, FIG. 5 is a top view of the inductor in the second example according to an embodiment of the present disclosure, and FIG. 6 is a side view of the inductor in the second example according to an embodiment of the present disclosure. As shown in FIGS. 4-6, a structure of the inductor is substantially the same as the structure in the first example, except that the first coil structure 11 and the second coil structure 12 in the inductor include only three layers of sub-coils. The three layers of sub-coils of the first coil structure 11 are indicated by 111a, 111b and 111c, respectively. The three layers of sub-coils of the second coil structure 12 are indicated by 121a, 121b, and 121c, respectively. Compared with the inductor with the four layers of sub-coils, the inductor with the three layers of sub-coils simplifies the quantity of layers, and reduces the quantity of layers of the conductive layers and the interlayer insulating layers, so that stress of a conductive layer and an interlayer insulating layer can be effectively reduced, and requirements on a material thickness and mechanical properties of the dielectric substrate can be reduced, which is beneficial to manufacturing of IPD devices with large area in the future.

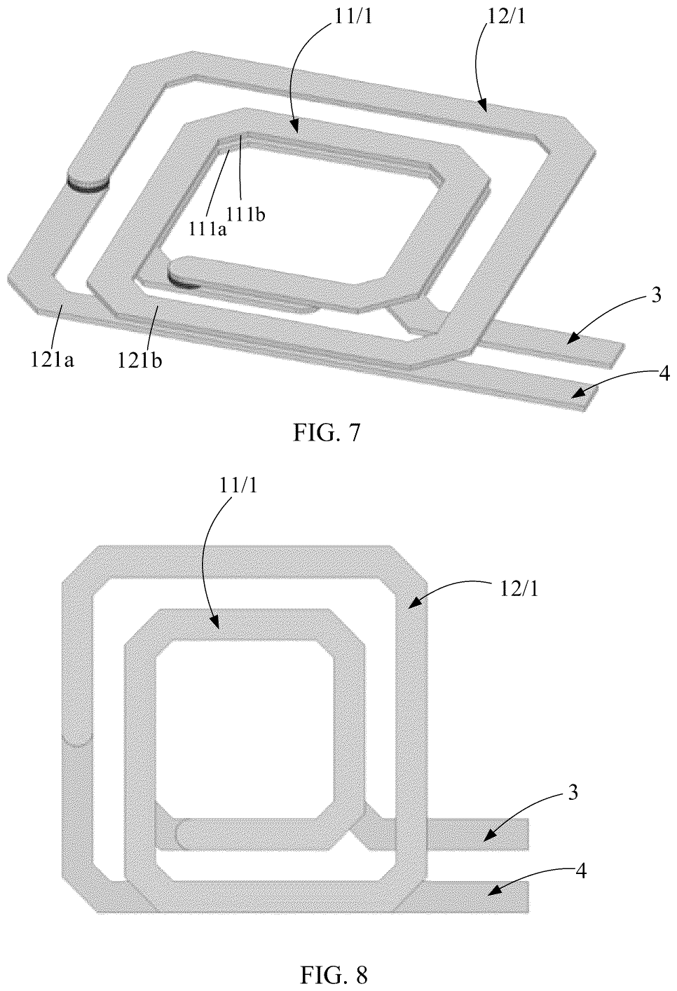

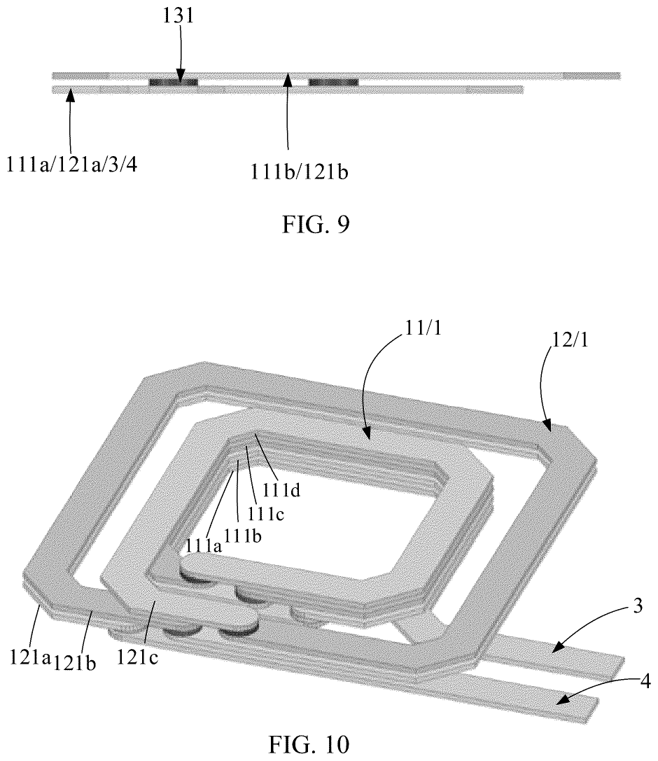

In a third example, FIG. 7 is a front view of an inductor in a third example according to an embodiment of the present disclosure, FIG. 8 is a top view of the inductor in the third example according to an embodiment of the present disclosure, and FIG. 9 is a side view of the inductor in the third example according to an embodiment of the present disclosure. As shown in FIGS. 7-9, a structure of the inductor is substantially the same as the structures in the first and second examples, except that the first coil structure 11 and the second coil structure 12 in the inductor include only two layers of sub-coils. The two layers of sub-coils of the first coil structure 11 are indicated by 111a and 111b, respectively. The two layers of sub-coils of the second coil structure 12 are indicated by 121a and 121b, respectively. By the design of the double-layer inductor structure, the inductance density can also be increased and an inductance utilization rate can be improved. In the double-layer structure, the first lead terminal 3 and the second lead terminal 4 of the inductor are also in a same plane, which is beneficial to the simplification and diversification of circuit design. The double-layer inductor can be manufactured only by two layers of sub-coils and two layers of interlayer insulating layers, thus reducing quantities of layers of the conductive layers and the interlayer insulating layers, reducing stress of the conductive layers and the interlayer insulating layers, reducing the process difficulty. The reduced film stress can further reduce a limitation on the thickness of the dielectric substrate, meanwhile, the lower thickness of the dielectric substrate is beneficial to volatilization of heat of radio frequency elements and broadens the application scenario of IPD devices.

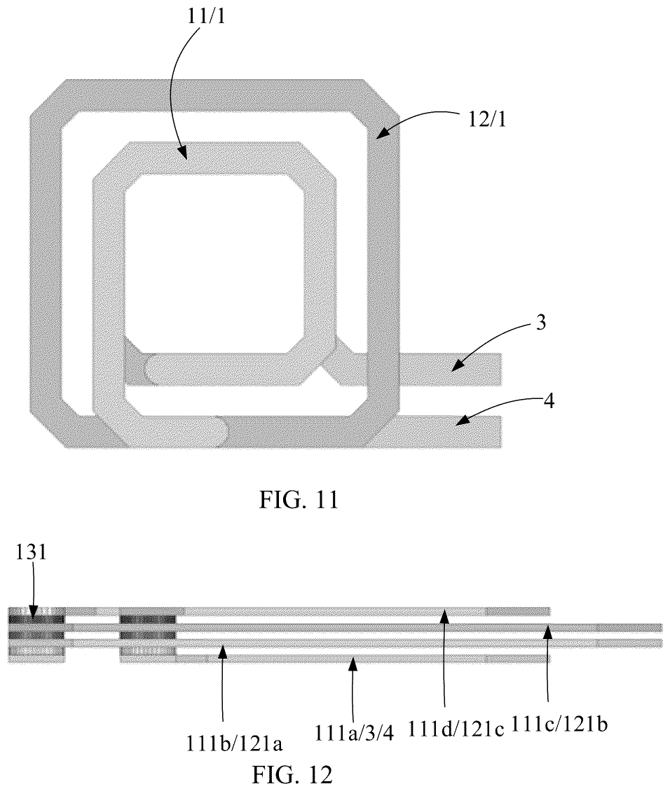

In a fourth example, FIG. 10 is a front view of an inductor in a fourth example according to an embodiment of the present disclosure, FIG. 11 is a top view of the inductor in the fourth example according to an embodiment of the present disclosure, and FIG. 12 is a side view of the inductor in the fourth example according to an embodiment of the present disclosure. As shown in FIGS. 10-12, a first coil structure 11 in a structure of the inductor includes four layers of sub-coils, a second coil structure 12 includes three layers of sub-coils. The four layers of sub-coils of the first coil structure 11 are indicated by 111a, 111b, 111c and 111d, respectively. The three layers of sub-coils of the second coil structure 12 are indicated by 121a, 121b, and 121c, respectively. The second layer of sub-coil 111b of the first coil structure 11 is disposed in a same layer as the first layer of sub-coil 121a of the second coil structure 12, the third layer of sub-coil 111c of the first coil structure 11 is disposed in a same layer as the second layer of sub-coil 121b of the second coil structure 12, and the fourth layer of sub-coil 111d of the first coil structure 11 is disposed in a same layer as the third layer of sub-coil 121c of the second coil structure 12, the first lead terminal 3 and the head end of the first layer of sub-coil 111a of the first coil structure 11 are electrically connected, disposed in a same layer and connected into an integrally-formed structure. The second lead terminal 4 and a head end of the first layer of sub-coil 121a of the second coil structure 12 are electrically connected through a second connection via penetrating an interlayer insulating layer between the second lead terminal 4 and the head end of the first layer of sub-coil 121a of the second coil structure 12. In this case, selection of the inductance value can be further improved by changing the quantity of the sub-coils of the second coil structure 12, preventing limitation on a range of the inductance values due to limitations on the first coil structure 11 and the second coil structure 12. Meanwhile, a change in the structure reduces the quantity of sub-coils of the second coil structure 12, and reduces a conductive density of a conductive film layer, and a structural stress of the film layer can be reduced partly. The change in the coil structure is also beneficial to cooperation between inductance elements and other electrical elements, expanding a utilization space of the inductor.

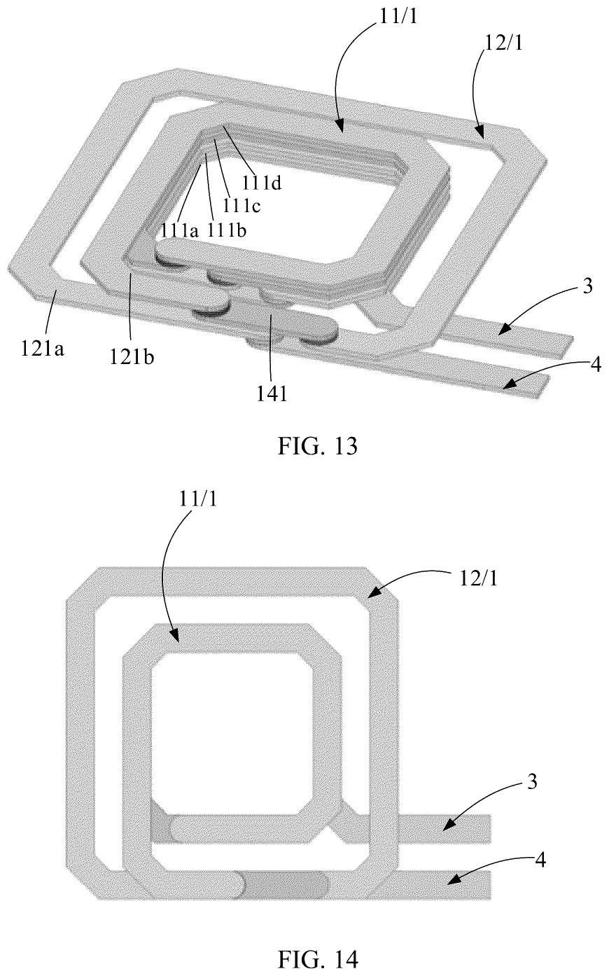

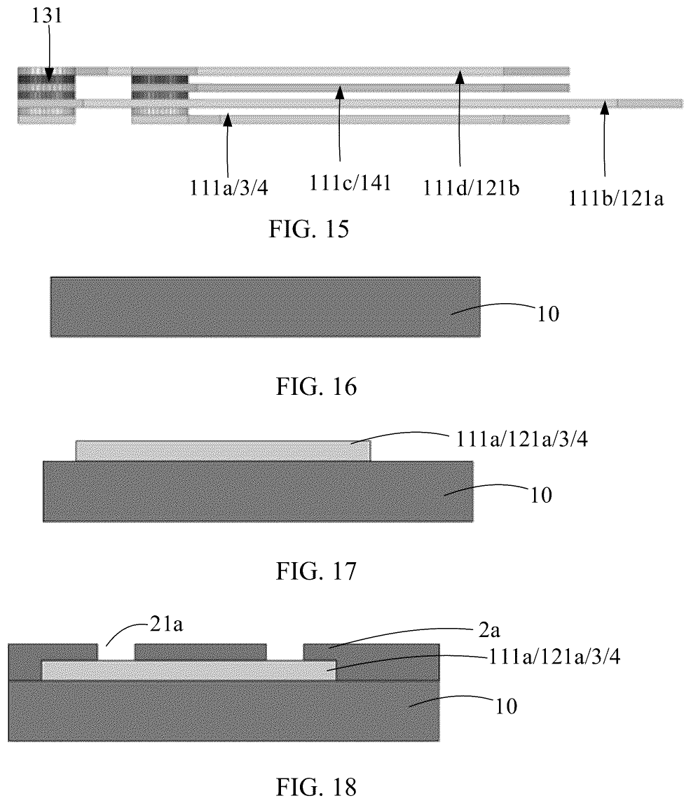

In a fifth example, FIG. 13 is a front view of an inductor in a fifth example according to an embodiment of the present disclosure, FIG. 14 is a top view of the inductor in the fifth example according to an embodiment of the present disclosure, and FIG. 15 is a side view of the inductor in the fifth example according to an embodiment of the present disclosure. As shown in FIGS. 13-15, a structure of the inductor is substantially the same as the structure in the fourth example, except that the second coil structure 12 includes two layers of sub-coils. The fourth layers of sub-coils of the first coil structure 11 are indicated by 111a, 111b, 111c and 111d, respectively. The two layers of sub-coils of the second coil structure 12 are indicated by 121a and 121b, respectively. The second layer of sub-coil 111b of the first coil structure 11 is disposed on the same layer as the first layer of sub-coil 121a of the second coil structure 12, the fourth layer of sub-coil 111d of the first coil structure 11 is disposed on a same layer as the second layer of sub-coil 121b of the second coil structure 12, the first layer of sub-coil 121a and the second layer of sub-coil 121b of the second coil structure 12 are electrically connected through a connection electrode 141 which is disposed in a same layer as the third layer of sub-coil 111c of the first coil structure 11. In this case, the connection electrode 141 and the first layer of sub-coil 121a of the second coil structure 12 are electrically connected through a via penetrating an interlayer insulating layer between the connection electrode 141 and the first layer of sub-coil 121a of the second coil structure 12, and the connection electrode 141 and the second layer of sub-coil 121b of the second coil structure 12 are electrically connected through a via penetrating an interlayer insulating layer between the connection electrode 141 and the second layer of sub-coil 121b of the second coil structure 12. The first lead terminal 3 and the head end of the first layer of sub-coil 111a of the first coil structure 11 are electrically connected, disposed in a same layer and connected into an integrally-formed structure. The second lead terminal and a head end of the first layer of sub-coil 121a of the second coil structure 12 are electrically connected through a second connection via penetrating through an interlayer insulating layer between the second lead terminal and the head end of the first layer of sub-coil 121a of the second coil structure 12. In this case, selection of the inductance value can be further improved by changing the quantity of the sub-coils of the second coil structure 12, preventing limitation on a range of the inductance values due to limitations on the first coil structure 11 and the second coil structure 12. Meanwhile, a change in the structure reduces the quantity of sub-coils of the second coil structure 12, and reduces a conductive density of a conductive film layer, and a structural stress of the film layer can be reduced partly. The change in the coil structure is also beneficial to cooperation between inductance elements and other electrical elements, expanding a utilization space of the inductor.

It should be understood that only a few exemplary inductor structures have been given above, and this does not limit the protection scope of the embodiments of the present disclosure.

In a second aspect, a method for manufacturing an inductor which can be used to manufacture any of the above-mentioned inductors is provided in an embodiment of the present disclosure. The method includes the following acts: providing a dielectric substrate 10, forming N coil structures on the dielectric substrate 10, the N coil structures are nested and electrically connected in sequence, wherein N is an integer greater than or equal to 2. The act of forming any coil structure includes forming, in sequence, a plurality of layers of sub-coils and at least one interlayer insulating layer between adjacent layers of sub-coils on the dielectric substrate 10; wherein adjacent layers of sub-coils are electrically connected through a first connection via penetrating the interlayer insulating layer between the adjacent layers of sub-coils.

In an inductor manufactured by the method for manufacturing an inductor according to an embodiment of the present disclosure, each coil structure of the inductor is formed by electrically connecting a plurality of layers of sub-coils, which can effectively increase a wiring length of the inductor, and with an increase of the wiring length of the inductor per unit area, an inductance density can be improved. Meanwhile, since the inductor is composed of a plurality of nested coil structures, an effective mutual inductance can be formed between an inner coil structure and an outer coil structure 1 by controlling a current flow direction of the coil structures, and the inductance density can be further improved.

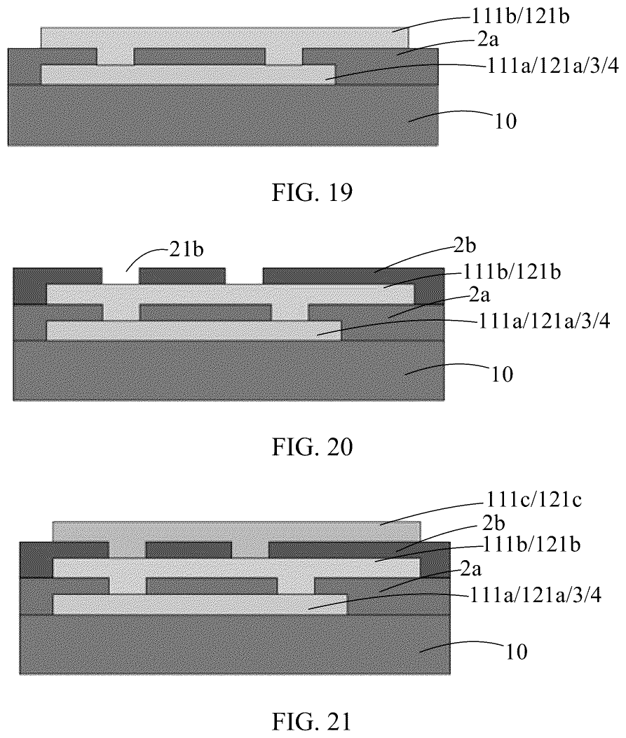

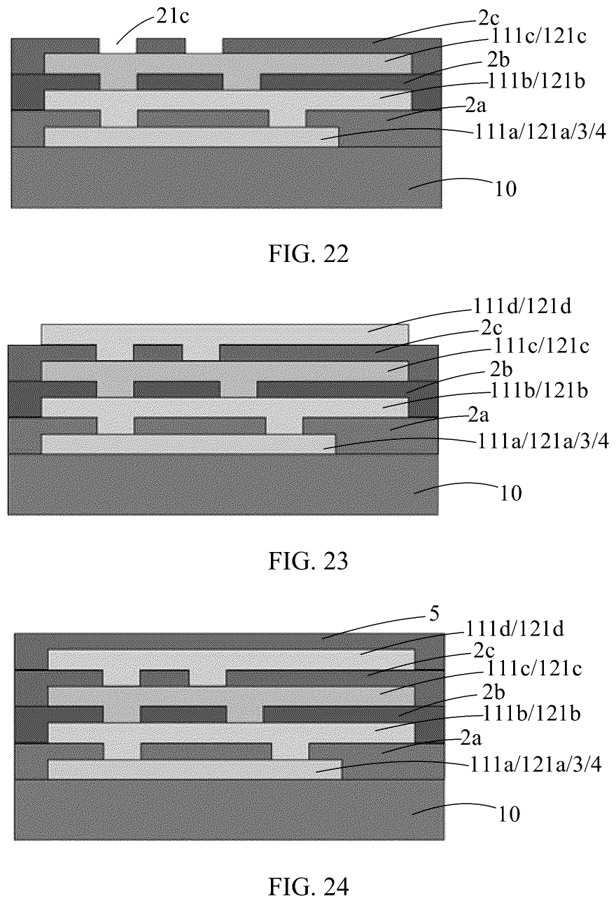

In order to more clearly explain the method for manufacturing an inductor according to an embodiment of the present disclosure, an inductor including two coil structures is taken as an example, i.e. N=2. An inner coil structure is referred to as a first coil structure 11 and an outer coil structure is referred to as a second coil structure 12. However, it should be understood that the quantity of the coil structures of the inductor is not limited to 2, and the quantity of the coil structures of the inductor can be specifically designed according to an inductance value requirement on the inductor in an actual product. Meanwhile, in the following examples, the first lead terminal 3 and the second lead terminal 4 formed directly on the dielectric substrate 10 and each of the first coil structure 11 and the second coil structure 12 including four layers of sub-coils are taken as an example. Three interlayer insulating layers between the sub-coils included in the inductor are referred to as a first interlayer insulating layer 2a, a second interlayer insulating layer 2b, and a third interlayer insulating layer 2c, respectively. FIG. 16 is a schematic diagram of an intermediate product formed in an act S11 of the method for manufacturing an inductor according to an embodiment of the present disclosure; FIG. 17 is a schematic diagram of an intermediate product formed in an act S12 of the method for manufacturing an inductor according to an embodiment of the present disclosure; FIG. 18 is a schematic diagram of an intermediate product formed in an act S13 of the method for manufacturing an inductor according to an embodiment of the present disclosure; FIG. 19 is a schematic diagram of an intermediate product formed in an act S14 of the method for manufacturing an inductor according to an embodiment of the present disclosure; FIG. 20 is a schematic diagram of an intermediate product formed in an act S15 of the method for manufacturing an inductor according to an embodiment of the present disclosure; FIG. 21 is a schematic diagram of an intermediate product formed in an act S16 of the method for manufacturing an inductor according to an embodiment of the present disclosure; FIG. 22 is a schematic diagram of an intermediate product formed in an act S17 of the method for manufacturing an inductor according to an embodiment of the present disclosure; FIG. 23 is a schematic diagram of an intermediate product formed in an act S18 of the method for manufacturing an inductor according to an embodiment of the present disclosure; FIG. 24 is a schematic diagram of an intermediate product formed in an act S19 of the method for manufacturing an inductor according to an embodiment of the present disclosure. The method for manufacturing an inductor is described in detail with reference to FIGS. 16-24 below.

In act S11, a dielectric substrate 10 is provided, as shown in FIG. 16.

In some examples, a dielectric substrate 10 with a thickness of 0.15 to 2 mm that can be used for mass production is prepared according to process equipment requirements, and a material of the dielectric substrate 10 can be selected as a material with high insulation and low dielectric loss, such as glass, high resistance silicon, ceramics, etc. The act S11 may include a cleaning process before manufacturing of the dielectric substrate 10. The cleaning process includes performing ultrasonic cleaning with organic solvents such as deionized water, ethanol, isopropanol and the like for at least 15 min, and drying by an oven after the ultrasonic cleaning, i.e., continuously drying at 75° C. for a certain time according to a solvent in the last cleaning.

In act S12, a first layer of sub-coil 111a of the first coil structure 11, a first layer of sub-coil 121a of the second coil structure 12, a first lead terminal 3 and a second lead terminal 4 are formed on the dielectric substrate 10, as shown in FIG. 17.

In some examples, the act S12 may include forming a first conductive film as a first seed layer on the dielectric substrate 10 by electroplating, electroless plating, or the like, or by sputtering, and then forming a first layer of sub-coil 111a of the first coil structure 11, a first layer of sub-coil 121a of the second coil structure 12, a first lead terminal 3, and a second lead terminal 4 by spin-coating photoresist, exposure developing, electroplating, electroless plating metal trace on a side of the first seed layer facing away from the dielectric substrate 10.

A material of the first conductive film is generally Au, Al, Ag, Cu and other metal materials. Thicknesses of the first layer of sub-coil of the first coil structure 11, the first layer of sub-coil of the second coil structure 12, the first lead terminal 3 and the second lead terminal 4 are generally between 0.1 and 20 μm. In order to ensure flatness of the first layer of sub-coil 111a of the first coil structure 11, the first layer of sub-coil 121a of the second coil structure 12, the first lead terminal 3 and the second lead terminal 4, upper surfaces (surfaces facing away from the dielectric substrate 10) of the first layer of sub-coil 111a of the first coil structure 11, the first layer of sub-coil 121a of the second coil structure 12, the first lead terminal 3 and the second lead terminal 4 can be treated by Chemical Mechanical Grinding (CMP for short).

In act S13, a first interlayer insulating layer 2a is formed on the dielectric substrate 10 where the act S12 is completed, and a first connection via 131a penetrating the first interlayer insulating layer 2a is formed. A quantity of the first connection vias 131a is two, one of the first connection vias is used for electrically connecting a tail end of the first layer of sub-coil 111a of the first coil structure 11 with a head end of the second layer of sub-coil 111b to be formed. The other first connection via 131a is used for electrically connecting a tail end of the first layer of sub-coil 121a of the second coil structure 12 with a head end of the second layer of sub-coil 121b to be formed, as shown in FIG. 18.

In some examples, the material of the first interlayer insulating layer 2a may be an inorganic material, such as silicon nitride, silicon oxide, etc. The act S13 may include manufacturing a first interlayer insulating layer 2a with a thickness of 1-20 um by a Physical Vapor Deposition (PVD for short) method or a Chemical Vapor Deposition (CVD for short) method. The material of the first interlayer insulating layer 2a may also be an organic material such as polyimide (PI for short) or another resin material. The act S13 may include patterning the interlayer insulating layer by a homogenizing process. Then a first connection via penetrating the first interlayer insulating layer 2a is formed by exposure and development.

In act S14, a second layer of sub-coil 111b of the first coil structure 11 and a second layer of sub-coil 121b of the second coil structure 12 are formed on the dielectric substrate 10 where the act S13 is completed, as shown in FIG. 19.

In some examples, the forming process in the act S14 may be the same as the forming process in the act S11, which is not be repeated herein.

In act S15, a second interlayer insulating layer 2b is formed on the dielectric substrate 10 where the act S14 is completed, and a first connection via 131b penetrating the second interlayer insulating layer 2b is formed. A quantity of the first connection vias 131b is two, one of the first connection vias is used for electrically connecting a tail end of the second layer of sub-coil 111b of the first coil structure 11 with a head end of the third layer of sub-coil 111c to be formed. The other first connection via 131b is used for electrically connecting a tail end of the second layer of sub-coil 121b of the second coil structure 12 with a head end of the third layer of sub-coil 121c to be formed, as shown in FIG. 20.

In some examples, the forming process in the act S15 may be the same as the forming process in the act S12, which is not be repeated herein.

In act S16, a third layer of sub-coil 111c of the first coil structure 11 and a third layer of sub-coil 121c of the second coil structure 12 are formed on the dielectric substrate 10 where the act S15 is completed, as shown in FIG. 21.

In some examples, the forming process in the act S16 may be the same as the forming process in the act S11, which is not be repeated herein.

In act S17, a third interlayer insulating layer 2c is formed on the dielectric substrate 10 where the act S16 is completed, and a first connection via 131c penetrating the third interlayer insulating layer 2c is formed. A quantity of the first connection vias 131c is two, one of the first connection vias 131c is used for electrically connecting a tail end of the third layer of sub-coil 111c of the first coil structure 11 with a head end of the fourth layer of sub-coil 111d to be formed. The other first connection via 131c is used for electrically connecting a tail end of the third layer of sub-coil 121c of the second coil structure 12 with a head end of the fourth layer of sub-coil 121d to be formed, as shown in FIG. 22.

In some examples, the forming process in the act S17 may be the same as the forming process in the act S12, which is not be repeated herein.

In act S18, a fourth layer of sub-coil 111d of the first coil structure 11 and a fourth layer of sub-coil 121d of the second coil structure 12 are formed on the dielectric substrate 10 where the act S17 is completed, as shown in FIG. 23.

In some examples, the forming process in the act S18 may be the same as the forming process in the act S11, which is not be repeated herein.

In act S19, a protective layer 5 is formed on the dielectric substrate 10 where the act S18 is completed, as shown in FIG. 24.

In some examples, the material of the protective layer 5 may be an inorganic material, such as silicon nitride, silicon oxide, etc. The act S19 may include manufacturing a protective layer 5 with a thickness of 1-20 um by a PVD method or a CVD method. The material of the protective layer 5 may also be an organic material such as PI or another resin material. The act S19 may include forming by a homogenizing process.

In a third aspect, a filter that includes any of the inductors described above is provided in an embodiment of the present disclosure. The filter may also include capacitors, resistors and other elements, which are not enumerated here.

Each coil structure of the inductor is formed by electrically connecting a plurality of layers of sub-coils, which can effectively increase a wiring length of the inductor, and with an increase of the wiring length of the inductor per unit area, an inductance density can be improved. Meanwhile, since the inductor is composed of a plurality of nested coil structures, an effective mutual inductance can be formed between an inner coil structure and an outer coil structure 1 by controlling a current flow direction of the coil structures, and the inductance density can be further improved.

In a fourth aspect, an electronic device that may include the filter described above is provided in an embodiment of the present disclosure.

It is to be understood that the above embodiments are only exemplary embodiments employed for the purpose of illustrating the principles of the present invention, however the present invention is not limited thereto. To those of ordinary skill in the art, various modifications and improvements may be made without departing from the spirit and substance of the present invention, and these modifications and improvements are also considered to be within the protection scope of the present invention.

1. An inductor comprising a dielectric substrate and N coil structures disposed on the dielectric substrate, wherein the N coil structures are nested and electrically connected in sequence, wherein N is an integer greater than or equal to 2; wherein,
any one of the coil structures comprises a plurality of layers of sub-coils disposed on the dielectric substrate in sequence, and at least one interlayer insulating layer is disposed between sub-coils disposed adjacently, and adjacent layers of sub-coils are electrically connected through a first connection via penetrating the interlayer insulating layer between the adjacent layers of sub-coils.

2. The inductor of claim 1, further comprising a first lead terminal and a second lead terminal, wherein the first lead terminal is electrically connected to a head end of a first coil structure, and the second lead terminal is electrically connected to a tail end of an N-th coil structure.

3. The inductor of claim 2, wherein the first lead terminal and the second lead terminal are disposed in a same layer and of a same material.

4. The inductor of claim 3, wherein the first lead terminal is electrically connected to a first layer of sub-coil of the first coil structure in a direction away from the dielectric substrate, and the second lead terminal is electrically connected to a first layer of sub-coil of the N-th coil structure in the direction away from the dielectric substrate.

5. The inductor of claim 4, wherein the first lead terminal is disposed in a same layer as the first layer of sub-coil of the first coil structure in the direction away from the dielectric substrate, and the first lead terminal and the first layer of sub-coil of the first coil structure are integrally formed; and/or,
the second lead terminal is disposed in a same layer as the first layer of sub-coil of the N-th coil structure in the direction away from the dielectric substrate, and the second lead terminal and the first layer of sub-coil of the N-th coil structure are integrally formed.

6. The inductor of claim 3, wherein the first lead terminal is electrically connected to a last layer of sub-coil of the first coil structure in a direction away from the dielectric substrate, and the second lead terminal is electrically connected to a last layer of sub-coil of the N-th coil structure in the direction away from the dielectric substrate.

7. The inductor of claim 6, wherein the first lead terminal is disposed in a same layer as the last layer of sub-coil of the first coil structure in the direction away from the dielectric substrate, and the first lead terminal and the last layer of sub-coil of the first coil structure are integrally formed; and/or,
the second lead terminal is disposed in a same layer as the last layer of sub-coil of the N-th coil structure in the direction away from the dielectric substrate, and the second lead terminal and the last layer of sub-coil of the N-th coil structure are integrally formed.

8. The inductor of claim 1, wherein each of the N coil structures comprises M layers of the sub-coils, wherein M is an integer greater than or equal to 2; sub-coils of k-th layers in all coil structures are disposed in a same layer, wherein k is an integer greater than or equal to 1 and less than or equal to N.

9. The inductor of claim 1, wherein quantities of layers in at least two coil structures in the N coil structures are not equal;
for any two of the coil structures with unequal quantities of layers of sub-coils, one of the any two coil structures comprises P layers of sub-coils, and the other one of the any two coil structures comprises Q layers of sub-coils; a coil structure comprising the P layers of sub-coils is referred to as a first coil structure, and a coil structure comprising the Q layers of sub-coils is referred to as a second coil structure, wherein P is an integer greater than or equal to 2, Q is an integer greater than or equal to 2, and P is greater than Q;
an i-th layer of sub-coil in the first coil structure and the i-th layer of sub-coil in the second coil structure are disposed in a same layer, and an (i+k)-th layer of sub-coil in the first coil structure and an (i+1)-th layer of sub-coil in the second coil structure are disposed in a same layer, wherein i is an integer greater than or equal to 1 and less than or equal to N, and k is an integer greater than or equal to 2 and less than or equal to N−i;
an i-th layer of sub-coil and an (i+1)-th layer of sub-coil of the second coil structure are electrically connected through a transfer electrode that is composed of at least one layer of sub-coil in (i+2)-th to (i+k−1)-th layers of sub-coils in the first coil structure.

10. A method for manufacturing an inductor, comprising: providing a dielectric substrate, forming N coil structures on the dielectric substrate, wherein the N coil structures are nested and electrically connected in sequence; wherein N is an integer greater than or equal to 2; wherein an act of forming any coil structure comprises:
forming, in sequence, a plurality of layers of sub-coils and at least one interlayer insulating layer between adjacent layers of sub-coils on the dielectric substrate; wherein adjacent layers of sub-coils are electrically connected through a first connection via penetrating the interlayer insulating layer between the adjacent layers of sub-coils.

11. The method for manufacturing an inductor of claim 10, further comprising forming a first lead terminal and a second lead terminal on the dielectric substrate, wherein the first lead terminal is electrically connected to a head end of a first coil structure, and the second lead terminal is electrically connected to a tail end of an N-th coil structure.

12. The method for manufacturing an inductor of claim 11, wherein the first lead terminal and a first layer of sub-coil of the first coil structure in a direction away from the dielectric substrate are formed by a single patterning process; and/or,
the second lead terminal and a first layer of sub-coil of the N-th coil structure in the direction away from the dielectric substrate are formed by a single patterning process.

13. The method for manufacturing an inductor of claim 11, wherein the first lead terminal and a last layer of sub-coil of the first coil structure in a direction away from the dielectric substrate are formed by a single patterning process; and/or,
the second lead terminal and a last layer of sub-coil of the N-th coil structure in the direction away from the dielectric substrate are formed by a single patterning process.

14. The method for manufacturing an inductor of claim 10, wherein each of the N coil structures comprises M layers of sub-coils, wherein M is an integer greater than or equal to 2; sub-coils of k-th layers in all coil structures are formed by a single patterning process, wherein k is an integer greater than or equal to 1 and less than or equal to N.

15. The method for manufacturing an inductor of claim 10, wherein quantities of layers in at least two coil structures in the N coil structures are not equal;
for any two of the coil structures with unequal quantities of layers of sub-coils, one of the any two coil structures comprises P layers of sub-coils, and the other one of the any two coil structures comprises Q layers of sub-coils; a coil structure comprising the P layers of sub-coils is referred to as a first coil structure, and a coil structure comprising the Q layers of sub-coils is referred to as a second coil structure, wherein P is an integer greater than or equal to 2, Q is an integer greater than or equal to 2, and P is greater than Q;
an i-th layer of sub-coil in the first coil structure and the i-th layer of sub-coil in the second coil structure are formed by a single patterning process, and an (i+k)-th layer of sub-coil in the first coil structure and an (i+1)-th layer of sub-coil in the second coil structure are formed by a single patterning process, wherein i is an integer greater than or equal to 1 and less than or equal to N, and k is an integer greater than or equal to 2 and less than or equal to N−i;
an i-th layer of sub-coil and an (i+1)-th layer of sub-coil of the second coil structure are electrically connected through a transfer electrode that is composed of at least one layer of sub-coil in (i+2)-th to (i+k−1)-th layers of sub-coils in the first coil structure.

16. A filter comprising the inductor of claim 1.

17. An electronic device comprising the filter of claim 16.

18. The inductor of claim 2, wherein each of the N coil structures comprises M layers of the sub-coils, wherein M is an integer greater than or equal to 2; sub-coils of k-th layers in all coil structures are disposed in a same layer, wherein k is an integer greater than or equal to 1 and less than or equal to N.

19. The inductor of claim 3, wherein each of the N coil structures comprises M layers of the sub-coils, wherein M is an integer greater than or equal to 2; sub-coils of k-th layers in all coil structures are disposed in a same layer, wherein k is an integer greater than or equal to 1 and less than or equal to N.

20. The inductor of claim 4, wherein each of the N coil structures comprises M layers of the sub-coils, wherein M is an integer greater than or equal to 2; sub-coils of k-th layers in all coil structures are disposed in a same layer, wherein k is an integer greater than or equal to 1 and less than or equal to N.
